(19) United States
(12) Patent Application Publication
(10) Pub. No.: US 2026/0144081 A1
(43) Pub. Date: May 21, 2026

(54) SEMICONDUCTOR PACKAGE AND METHOD OF MANUFACTURING SEMICONDUCTOR PACKAGE

(71) Applicant: SAMSUNG ELECTRONICS CO., LTD., Suwon-si (KR)

(72) Inventors: Gihun LEE, Suwon-si (KR); Eunbeom JEON, Suwon-si (KR)

(73) Assignee: SAMSUNG ELECTRONICS CO., LTD., Suwon-si (KR)

(21) Appl. No.: 19/374,575

(22) Filed: Oct. 30, 2025

(30) Foreign Application Priority Data
Nov. 15, 2024 (KR) 10-2024-0162978

(51) Int. Cl. H01L 23/544; H01L 21/56; H01L 23/00; H01L 23/29; H01L 23/31

(52) U.S. Cl. CPC H10W 46/00; H10W 74/014; H10W 74/016; H10W 74/111; H10W 46/103; H10W 46/607; H10W 72/20; H10W 74/47

(57) ABSTRACT

A semiconductor package may include a package substrate including a chip mounting region; a semiconductor chip on the chip mounting region of the package substrate; a molding member on the semiconductor chip and the package substrate, the molding member including at least one marking groove in an upper surface of the molding member; and at least one marking pattern in the at least one marking groove.

### CROSS-REFERENCE TO RELATED APPLICATION

This application claims priority under 35 U.S.C. § 119 to Korean Patent Application No. 10-2024-0162978, filed on Nov. 15, 2024, in the Korean Intellectual Property Office (KIPO), the disclosure of which is herein incorporated by reference in its entirety.

### BACKGROUND

### 1. Field

Some example embodiments of the present disclosure relate to a semiconductor package and a method of manufacturing the semiconductor package. More particularly, some example embodiments of the present disclosure relate to a semiconductor package including a semiconductor chip stacked in a flip chip bonding manner and a method of manufacturing the same.

### 2. Description of Related Art

In manufacturing a flip chip package, a semiconductor chip may be placed on a package substrate, a molded underfill (MUF) process may be performed to form a molding member, and a marking pattern may be formed on an upper surface of the molding member. The marking pattern may have an engraved shape by irradiating an upper surface of the molding member with a laser beam. During a subsequent reliability evaluation such as a thermal cycle (TC) test, stress may be concentrated on the laser marking area, causing cracks.

Further, during the molded underfill process, since a gap fill space of the molding material on the upper surface of the semiconductor chip may be larger than a gap fill space between a lower surface of the semiconductor chip and an upper surface of the package substrate, a difference in flow speed between the molding material flowing through upper and lower spaces of the semiconductor chip may occur. Accordingly, there is a problem that voids occur in the molding member below the lower surface of the semiconductor chip.

### SUMMARY

According to some example embodiments of the present disclosure, a semiconductor package capable of prevent voids from occurring in a molding member and having improved reliability may be provided.

According to some example embodiments of the present disclosure, a method of manufacturing the semiconductor package may be provided.

According to some example embodiments of the present disclosure, as semiconductor package may be provided and include: a package substrate including a chip mounting region; a semiconductor chip on the chip mounting region of the package substrate; a molding member on the semiconductor chip and the package substrate, the molding member including at least one marking groove in an upper surface of the molding member; and at least one marking pattern in the at least one marking groove.

According to some example embodiments of the present disclosure, as semiconductor package may be provided and include: a package substrate including a chip mounting region; a semiconductor chip on the chip mounting region of the package substrate, wherein the semiconductor chip includes a first surface that faces the package substrate, and conductive bumps are on the first surface; a molding member on the semiconductor chip and the package substrate, wherein the molding member includes at least one marking groove in an upper surface of the molding member; and at least one marking pattern in the at least one marking groove, the at least one marking pattern including a protrusion shape, wherein the at least one marking pattern includes an ink material.

According to some example embodiments of the present disclosure, as semiconductor package may be provided and include: a package substrate including a chip mounting region, and at least one molding material passage hole in the chip mounting region; a semiconductor chip on the chip mounting region of the package substrate, wherein the semiconductor chip includes a first surface that faces the package substrate, and conductive bumps are on the first surface; a molding member on the semiconductor chip and the package substrate, the molding member being in a gap between the package substrate and the at least one molding material passage hole, and the molding member including at least one marking groove in an upper surface of the molding member; and at least one marking pattern in the at least one marking groove, the at least one marking pattern including a protrusion shape, wherein each of a depth of the at least one marking groove from the upper surface of the molding member and a height of the at least one marking pattern from a bottom surface of the at least one marking groove is within a range of 10 μm to 50 μm.

According to some example embodiments of the present disclosure, a semiconductor package may include a package substrate, a semiconductor chip mounted on the package substrate via conductive bumps, a molding member that covers the semiconductor chip on the package substrate and has at least one engraved marking groove with an engrave shape in an upper surface of the molding member, and a marking pattern with a protrusion shape (e.g., an embossed shape) in the marking groove.

Since the marking pattern may be formed by an inkjet printing manner and may have the embossed shape, an upper surface of the marking pattern does not have a step with the upper surface of the molding member and does not cause damage to the marking area due to a laser processing method, to thereby prevent stress from being concentrated on the marking area and cracks from being caused during a reliability evaluation such as a subsequent TC test.

In addition, a protruding rib for forming the marking groove of the molding member may be provided as a structure for controlling the flow of a molding material, such as an epoxy mold compound (EMC), within a mold in a transfer molding process for forming the molding member. The protruding rib may reduce a difference in speed between the molding material passing through an upper space above the semiconductor chip and the molding material passing through a lower space under the semiconductor chip within a cavity of a mold. Accordingly, it may be possible to prevent a void from occurring within the molding member between the package substrate and the semiconductor chip.

### BRIEF DESCRIPTION OF DRAWINGS

Example embodiments will be more clearly understood from the following detailed description taken in conjunction with the accompanying drawings. FIGS. 1 to 16 represent non-limiting example embodiments as described herein.

FIG. 1 is a plan view illustrating a semiconductor package in accordance with example embodiments.

FIG. 2 is an enlarged cross-sectional view illustrating a portion “A” in FIG. 1.

FIG. 3 is a plan view of FIG. 1.

FIGS. 4 to 11 are views illustrating a method of manufacturing a semiconductor package in accordance with example embodiments.

FIG. 12 is a plan view illustrating a semiconductor package in accordance with example embodiments.

FIGS. 13 and 14 are views illustrating a process of forming a molding member on a package substrate by a molding apparatus.

FIG. 15 is a cross-sectional view illustrating the molding member formed on the package substrate by the molding apparatus of FIG. 13.

FIG. 16 is a cross-sectional view illustrating a semiconductor package in accordance with example embodiments.

### DETAILED DESCRIPTION

Hereinafter, non-limiting example embodiments of the present disclosure will be explained in detail with reference to the accompanying drawings.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

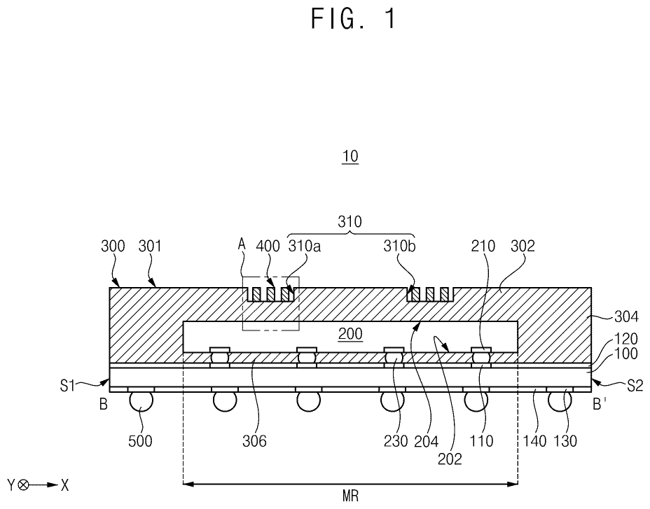

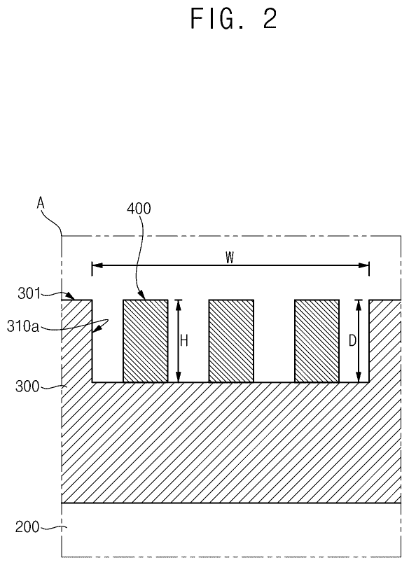

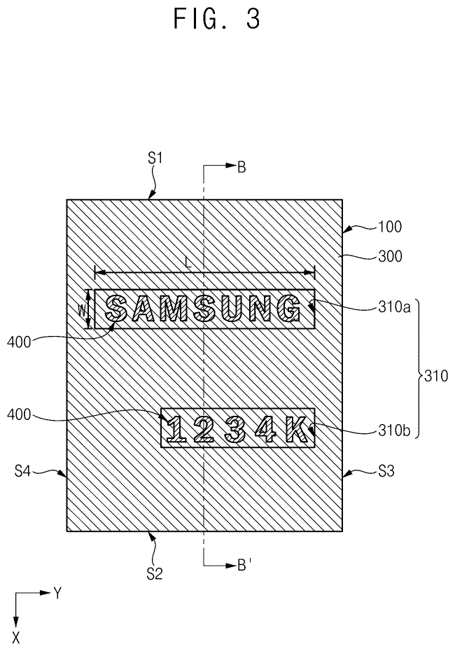

FIG. 1 is a plan view illustrating a semiconductor package in accordance with example embodiments. FIG. 2 is an enlarged cross-sectional view illustrating a portion “A” in FIG. 1. FIG. 3 is a plan view of FIG. 1. FIG. 1 is a cross-sectional view taken along a line B-B′ in FIG. 3.

Referring to FIGS. 1 to 3, a semiconductor package 10 may include a package substrate 100, a semiconductor chip 200 disposed on the package substrate 100, a molding member 300 covering the semiconductor chip 200 on the package substrate 100, and a marking pattern 400 provided on an upper surface of the molding member 300. Additionally, the semiconductor package 10 may further include external connection members 500.

In example embodiments, the package substrate 100 may be a substrate having an upper surface and a lower surface opposite to each other. For example, the package substrate 100 may be a printed circuit board (PCB). The printed circuit board may be a multilayer circuit board having vias and various circuits therein.

The package substrate 100 may include a plurality of stacked insulating layers and wirings provided in the insulating layers. Additionally, the package substrate 100 may include a plurality of upper substrate pads 110 and a plurality of lower substrate pads 130. The wirings may include internal wirings that serve as channels for electrical connection with different types of semiconductor chips.

The upper substrate pads 110 may be exposed from the upper surface of the package substrate 100. A first upper insulating layer 120 may be provided on the package substrate 100, and at least portions of the upper substrate pads 110 may be exposed through the first upper insulating layer 120. The lower substrate pads 130 may be exposed from the lower surface of the package substrate 100. A lower insulating layer 140 may be provided on the package substrate 100, and at least portions of the lower substrate pads 130 may be exposed through the lower insulating layer 140.

In example embodiments, the package substrate 100 may include a chip mounting region MR in a middle region of the package substrate 100. The upper substrate pads 110 may be disposed within the chip mounting region MR of the package substrate 100. The upper substrate pads 110 may be arranged in an array in the chip mounting region MR. The package substrate 100 may have a rectangular shape with a first side (e.g., a short side) and a second side (e.g., a long side).

In example embodiments, the semiconductor chip 200 may be disposed on the chip mounting region MR. The semiconductor chip 200 may be mounted on the chip mounting region MR of the package substrate 100 via conductive bumps 230. The semiconductor chip 200 may be disposed such that a frontside surface 202 (e.g., an active surface) of the semiconductor chip 200, at (e.g., in or on) which chip pads 210 are formed, faces the package substrate 100. The chip pads 210 may be arranged in an array over an entirety of the frontside surface 202 of the semiconductor chip 200.

The semiconductor chip 200 may be mounted on the package substrate 100 using a flip chip bonding method. The chip pads 210 of the semiconductor chip 200 may be electrically connected to the upper substrate pads 110 of the package substrate 100 by the conductive bumps 230. A gap may be formed between the semiconductor chip 200 and the package substrate 100 due to the conductive bumps 230.

For example, the conductive bump 230 may include a micro bump (uBump). Each of the conductive bumps 230 may include a conductive pillar as a lower bump and a solder as an upper bump. The conductive pillar may include a copper pillar (Cu pillar). The solder may include, for example, tin (Sn), tin/silver (Sn/Ag), tin/copper (Sn/Cu), tin/indium (Sn/In), tin/silver/copper (Sn/Ag/Cu), etc.

The conductive bump 230 under the semiconductor chip 200 may be electrically connected to the external connection member 500 by the upper substrate pad 110, the wirings in the package substrate 100, and the lower substrate pad 130. Accordingly, the semiconductor chip 200 may be electrically connected to an external device through the conductive bumps 230.

The semiconductor chip 200 may include a memory chip including a memory circuit. For example, the semiconductor chip may include volatile memory devices such as static random-access memory (SRAM) devices, dynamic random-access memory (DRAM) devices, etc., and non-volatile memory devices such as flash memory devices, parameter random-access memory (PRAM) devices, magnetoresistive random-access memory (MRAM) devices, resistive random-access memory (ReRAM) devices, etc.

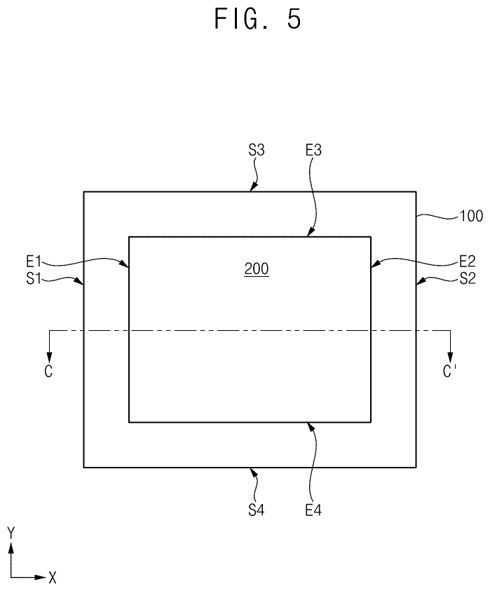

As illustrated in FIG. 3, the package substrate 100 may include a first side portion S1 and a second side portion S2 extending in a direction parallel to a second direction (e.g., Y direction) and facing away from each other, and a third side portion S3 and a fourth side portion S4 extending in a direction parallel to a first direction (e.g., X direction) perpendicular to the second direction and facing away from each other. The semiconductor chip 200 may have a rectangular shape with four sides when viewed in a plan view. With reference to FIG. 5, the semiconductor chip 200 may have a first chip side E1 and a second chip side E2 that extend in a direction parallel to the second direction (e.g., Y direction) and face away from each other, and a third chip side E3 and a fourth chip side E4 that extend in a direction parallel to the first direction (e.g., X direction) and face away from each other.

In example embodiments, the molding member 300 may cover the semiconductor chip 200 on the package substrate 100. The molding member 300 may include an epoxy mold compound (EMC). The molding member 300 may be formed by a molded underfill (MUF) process using a molding apparatus.

The molding member 300 may include a first molding portion 302 that covers the upper surface of the semiconductor chip 200 and a second molding portion 304 that covers the upper surface of the package substrate 100 around the semiconductor chip 200. The first molding portion 302 of the molding member 300 may have a height within a range of 150 μm to 250 μm from the upper surface of the semiconductor chip 200.

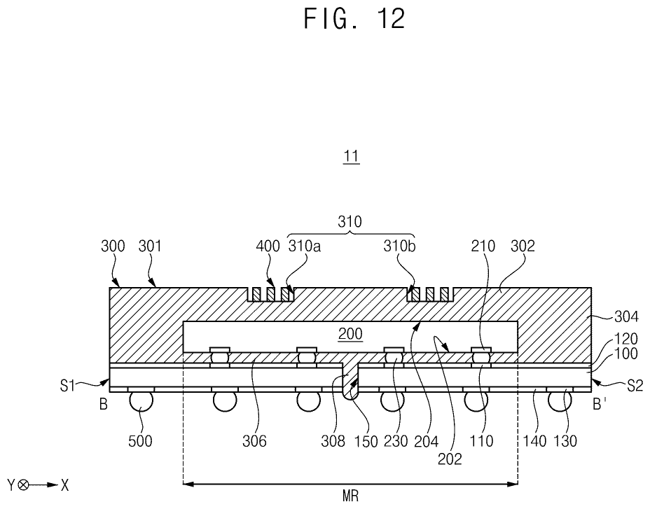

In addition, the molding member 300 may include a third molding portion 306 that fills a gap between the package substrate 100 and the semiconductor chip 200. According to some embodiments, the molding member 300 may further include a fourth molding portion 308 (see FIG. 12) that fills the inside of the at least one molding material passage hole 150 (see FIG. 12).

In example embodiments, the molding member 300 may have at least one marking groove 310 provided in an upper surface 301 of the molding member 300. The marking groove 310 may have an engraved shape with a depth D (e.g., a preset depth) from the upper surface 301 of the molding member 300. The depth D of the marking groove 310 may be within a range of 10 μm to 50 μm.

As illustrated in FIGS. 2 and 3, the at least one marking groove 310 may have a rectangular shape having a length L in the second direction (e.g., Y direction) and a width W in the first direction (e.g., X direction) when viewed in a plan view. However, embodiments of the present disclosure are not limited thereto, and the marking groove 310 may have various shapes, such as a circular, oval, or diamond shape. The length L in the second direction (e.g., Y direction) of the marking groove 310 may be within a range of 5 mm to 10 mm, and the width W in the first direction (e.g., X direction) of the marking groove 310 may be within a range of 1 mm to 3 mm.

For example, the at least one marking groove 310 may include a first marking groove 310a and a second marking groove 310b that are spaced apart from each other in the first direction (e.g., X direction). However, embodiments of the present disclosure are not limited thereto, and the at least one marking groove 310 may include three or more marking grooves that are spaced apart from each other.

The depth, length, width, number, and shapes of the marking grooves may be determined in consideration of flow conditions of a molding material in a transfer molding process for forming the molding member.

In example embodiments, the marking pattern 400 may be provided in the at least one marking groove 310 that is formed in the upper surface 301 of the molding member 300. The marking pattern 400 may be formed by applying a liquid on a bottom surface of the at least one marking groove 310 using an inkjet printing method. The liquid may include ink, etc. The ink may include red (R), green (G), and blue (B) inks in which pigment particles are mixed in a solvent.

The marking pattern 400 formed by the inkjet printing method may have a protrusion shape (e.g., an embossed shape) protruding from the bottom surface of the at least one marking groove 310. The marking pattern 400 of the embossed shape may indicate a manufacturer, a manufacturing date, a serial number, etc. A height H of the marking pattern 400 from the bottom surface of the marking groove 310 may be equal to or smaller than the depth D of the marking groove 310. The height H of the marking pattern 400 may be within a range of 10 μm to 50 μm.

In example embodiments, the lower substrate pads 130 may be formed at (e.g., in or on) the lower surface of the package substrate 100 to transmit electrical signals therethrough. The external connection member 500 may be disposed on the lower substrate pad 130 of the package substrate 100 for electrical connection with an external device. For example, the external connection member 500 may be a solder ball. The semiconductor package 10 may be mounted on a module substrate using the solder balls to form a memory module.

As mentioned above, the semiconductor package 10 may include the package substrate 100, the semiconductor chip 200 mounted on the package substrate 100 via the conductive bumps 230, the molding member 300 that covers the semiconductor chip 200 on the package substrate 100 and has the at least one marking groove 310 (e.g., at least one engraved marking groove) formed in the upper surface 301 of the molding member 300, and the marking pattern 400 (e.g., an embossed marking pattern) provided in the at least one marking groove 310.

Since the marking pattern 400 may be formed by an inkjet printing method and have the embossed shape, an upper surface of the marking pattern 400 does not have a step with the upper surface 301 of the molding member 300, and does not cause damage to the marking area due to a laser processing method, to thereby prevent stress from being concentrated on the marking area and cracks from being caused during a reliability evaluation such as a subsequent thermal cycle (TC) test.

In addition, a protruding rib for forming the marking groove 310 of the molding member 300 may be provided as a structure for controlling the flow of a molding material, such as EMC, within a mold in a transfer molding process for forming the molding member 300. The protruding rib may reduce a difference in flow speed between the molding material passing through an upper space on the semiconductor chip 200 within the cavity of the mold and the molding material passing through a lower space under the semiconductor chip 200. Accordingly, it may be possible to prevent a void from occurring within the molding member 300 between the package substrate 100 and the semiconductor chip 200.

Hereinafter, a method of manufacturing the semiconductor package in FIG. 1 will be explained.

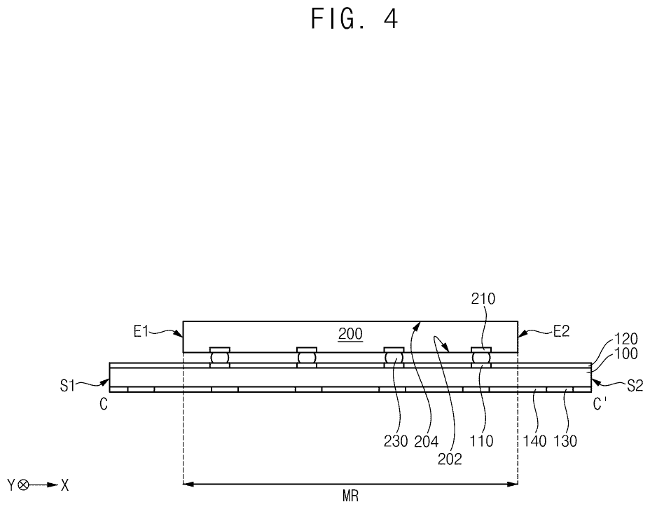

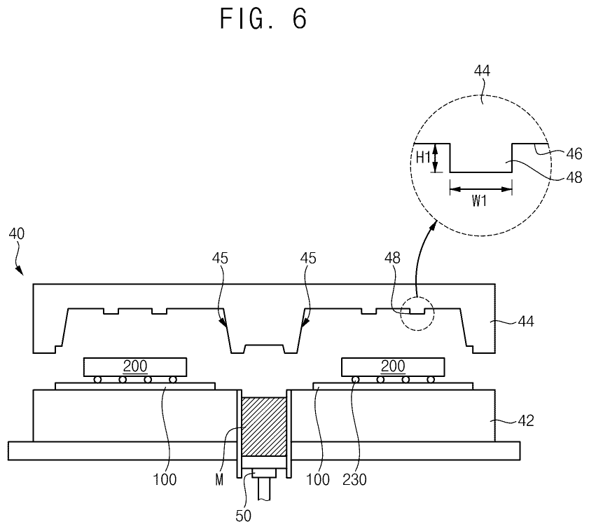

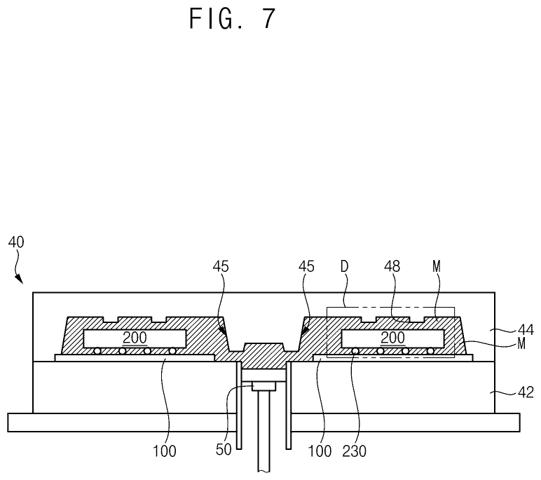

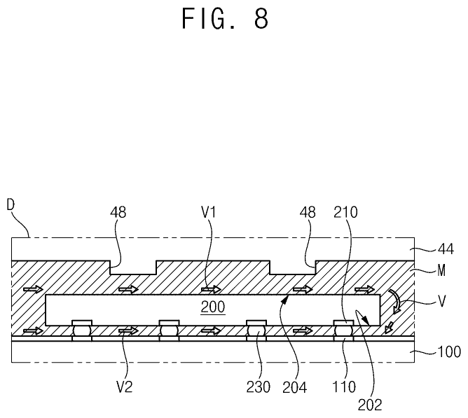

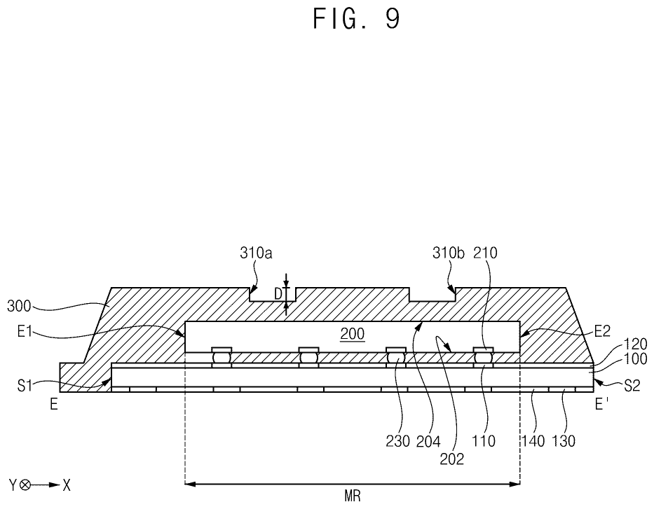

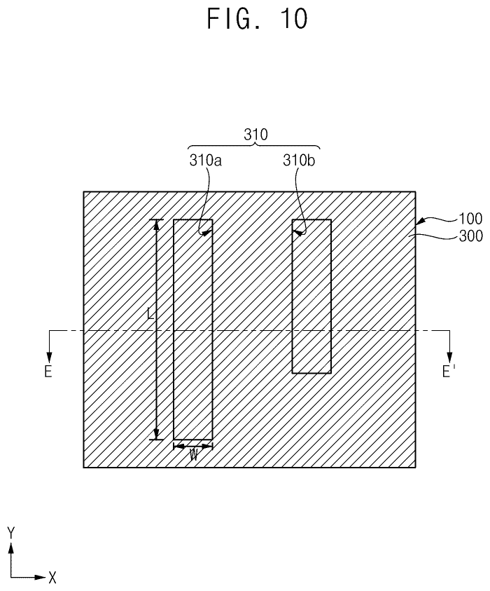

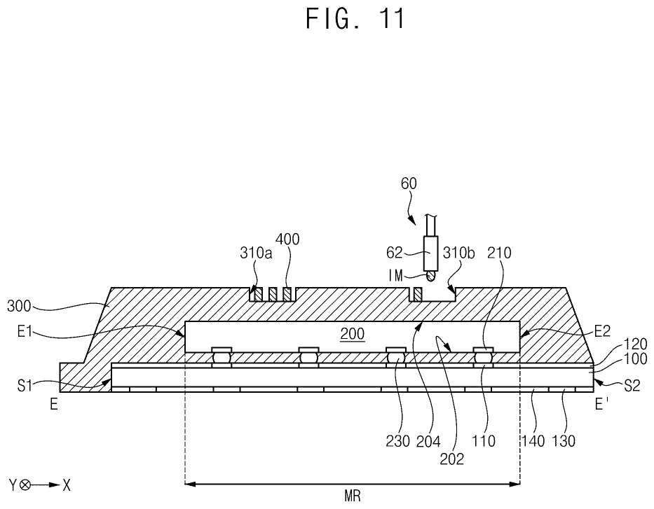

FIGS. 4 to 11 are views illustrating a method of manufacturing a semiconductor package in accordance with example embodiments. FIG. 4 is a cross-sectional view illustrating a semiconductor chip mounted on a package substrate. FIG. 5 is a plan view of FIG. 4. FIGS. 6 to 8 are views illustrating a process of forming a molding member on the package substrate by a molding apparatus. FIG. 9 is a cross-sectional view illustrating the molding member formed on the package substrate by the molding apparatus of FIG. 6. FIG. 10 is a plan view of FIG. 9. FIG. 11 is a cross-sectional view illustrating a process of forming a marking pattern on the molding member by an inkjet printing apparatus. FIG. 4 is a cross-sectional view taken along a line C-C′ in FIG. 5. FIG. 8 is an enlarged cross-sectional view illustrating a portion “D” in FIG. 7. FIG. 9 is a cross-sectional view taken along a line E-E′ in FIG. 10.

Referring to FIGS. 4 to 7, a semiconductor chip 200 may be mounted on a package substrate 100 with conductive bumps 230 interposed therebetween.

In example embodiments, a strip substrate including a plurality of package substrates 100 may be prepared, and individualized ones of the semiconductor chips 200 may be disposed on the strip substrate. The package substrate 100 may be a multilayer circuit board having an upper surface and a lower surface opposite to each other. For example, the strip board may be a printed circuit board (PCB) including wirings respectively provided in a plurality of layers and vias connected to the wirings.

According to some embodiments, as an example, several to several tens of semiconductor chips 200 may be mounted on one strip substrate. The strip substrate may be cut along a cutting region by a subsequent sawing process to be individualized into a semiconductor package.

As illustrated in FIG. 4, the semiconductor chip 200 may be mounted on a chip mounting region MR of the package substrate 100 using a flip chip bonding method.

In example embodiments, the semiconductor chip 200 may have a first surface (e.g., a frontside surface 202) at (e.g., in or on) which chip pads 210 are formed, and a second surface (e.g., a backside surface 204) opposite to the frontside surface 202. The semiconductor chip 200 may be placed such that the frontside surface 202 (e.g., active surface) at (e.g., in or on) which the chip pads 210 are formed faces the package substrate 100.

As illustrated in FIG. 5, the package substrate 100 may include a first side portion S1 and a second side portion S2 extending in a direction parallel to a second direction (e.g., Y direction) and facing away from each other, and a third side portion S3 and a fourth side portion S4 extending in a direction parallel to a first direction (e.g., X direction) perpendicular to the second direction (e.g., Y direction) and facing away from each other. The semiconductor chip 200 may have a rectangular shape with four sides when viewed in a plan view. The semiconductor chip 200 may have a first chip side E1 and a second chip side E2 that extend in a direction parallel to the second direction (e.g., Y direction) and face away from each other, and a third chip side E3 and a fourth chip side E4 that extend in a direction parallel to the first direction (X direction) and face away from each other.

In particular, the conductive bumps 230, as conductive connecting members, may be formed on the chip pads 210 of the semiconductor chip 200, flux may be applied on surfaces of the conductive bumps 230, and the semiconductor chip 200 may be placed on the package substrate 100. The conductive bumps 230 may be interposed between the package substrate 100 and the semiconductor chip 200. The conductive bumps 230 may be placed on the upper substrate pads 110 of the package substrate 100. Then, a reflow process may be performed to bond the conductive bumps 230 on corresponding ones of the upper substrate pads 110.

For example, the conductive bumps 230 may be formed by a plating process. Alternatively, the conductive bumps 230 may be formed by a screen printing method, a deposition method, or the like. For example, each of the conductive bumps 230 may include a conductive pillar as a lower bump and a solder as an upper bump. The conductive pillar may include a copper pillar. The solder may include, for example, tin (Sn), tin/silver (Sn/Ag), tin/copper (Sn/Cu), tin/indium (Sn/In), tin/silver/copper (Sn/Ag/Cu), etc.

Referring to FIGS. 6 to 10, a molding member 300 may be formed on the package substrate 100 to cover the semiconductor chip 200.

As illustrated in FIGS. 6 and 7, a molded underfill (MUF) process may be performed using a molding apparatus 40. The molding apparatus 40 may include a mold having a lower mold 42 and an upper mold 44 that are clamped to each other to form a molding space 45 for molding the semiconductor chips 200. The molding apparatus 40 may be a transfer molding apparatus that transfers a liquid molding material (e.g., the molding material M) into the molding space 45 to mold the semiconductor chips 200.

The semiconductor chip 200 may be placed in the molding space 45, and the molding material M may flow under high temperature and pressure while the lower mold 42 and the upper mold 44 are clamped, so that the liquid molding material M flows inside the molding space 45 and then solidifies to form the molding member 300 that covers the semiconductor chip 200. For example, the molding material M may include epoxy mold compound (EMC).

The molding material M in a tablet state from a molding material supply may be provided onto a plunger 50 and may be heated to have fluidity. Then, as the plunger 50 rises, the liquid molding material (e.g., the molding material M) may flow into the molding space 45 by the pressure of the plunger 50 and then solidified to form the molding member 300 on the strip substrate.

In example embodiments, the molding apparatus 40 may include at least one protruding rib 48 that protrudes from a lower surface 46 of the upper mold 44 and extends into the molding space 45. The protruding rib 48 may extend in a direction orthogonal to a direction in which the molding material M flows within the molding space 45. Accordingly, a marking groove 310 corresponding to the protruding rib 48 may be formed on an upper surface of the molding member 300. A lower surface of the protruding rib 48 may be flat. A height H1 of the protruding rib 48 may correspond to (e.g., be equal to or substantially equal to) a depth D of the marking groove 310, and a length and a width W1 of the protruding rib 48 may correspond to (e.g., be equal to or substantially equal to) the length L and the width W of the marking groove 310.

As illustrated in FIG. 8, the protruding ribs 48 formed on the lower surface 46 of the upper mold 44 may serve as a structure for controlling a flow of the molding material M in the transfer molding process. Since upper and lower spaces above and under the semiconductor chip 200 within the molding space 45 may be different, a difference in flow speed between the molding material M flowing through the upper and lower spaces may exist. The molding material M injected into the molding space 45 (e.g., a cavity) may move through the upper space above the semiconductor chip 200 at a first speed V1 and may move through the lower space between the semiconductor chip 200 and the package substrate 100 at a second speed V2 smaller than the first speed V1. According to a comparative embodiment, since the flow speed of a molding material flowing in the space between a semiconductor chip and a package substrate may be relatively slow, voids may be generated in the mold.

According to embodiments of the present disclosure, the protruding ribs 48 that serve as flow control members may reduce a height (e.g., gap) between an upper surface of the semiconductor chip 200 and the lower surface 46 of the upper mold 44, to thereby reduce the difference in flow speed between the molding material M flowing through the upper space and the lower space.

The mold (e.g., the molding apparatus 40) may be provided with a vent for exhausting gas in the molding space as the molding material M is introduced into the cavity. A vortex V of the molding material M may be generated at one end portion of the molding space adjacent to the vent. The protruding ribs 48 may control the flow speed at one end portion of the molding space to prevent the generation of the vortex.

As illustrated in FIGS. 9 and 10, the molding member 300 formed by the molding apparatus 40 may have the at least one marking groove 310 in the upper surface of the molding member 300 corresponding to the at least one protruding rib 48. For example, the at least one marking groove 310 may have a rectangular shape having a length L in the second direction (e.g., Y direction) and a width W in the first direction (e.g., X direction) when viewed in a plan view. However, embodiments of the present disclosure are not limited thereto, and the marking groove 310 may have various shapes, such as a circular, oval, or diamond shape. The length L in the second direction (e.g., Y direction) of the marking groove 310 may be within a range of 5 mm to 10 mm, and the width W in the first direction (e.g., X direction) of the marking groove 310 may be within a range of 1 mm to 3 mm. The depth D of the marking groove 310 may be within a range of 10 μm to 50 μm.

For example, the at least one marking groove 310 may include a first marking groove 310a and a second marking groove 310b that are spaced apart from each other in the first direction (X direction). However, embodiments of the present disclosure are not limited thereto, and the at least one marking groove 310 may include three or more marking grooves that are spaced apart from each other.

Referring to FIG. 11, a marking pattern 400 may be formed in the at least one marking groove 310 of the molding member 300.

In example embodiments, the marking pattern 400 may be formed using an inkjet printing apparatus 60. The inkjet printing apparatus 60 may form the marking pattern 400 by applying a liquid IM on the bottom surface of the at least one marking groove 310 in an inkjet printing manner. The liquid may include ink, etc. The ink may include red (R), green (G), and blue (B) inks in which pigment particles are mixed in a solvent.

The inkjet printing apparatus 60 may include a discharge nozzle 62 for discharging the liquid IM on the bottom surface of the at least one marking groove 310. The discharge nozzle 62 may have a piezoelectric element. The timing and amount of the liquid IM that is dispensed may be controlled by using the piezoelectric element.

The marking pattern 400 formed by the inkjet printing method may have an embossed shape protruding from the bottom surface of the at least one marking groove 310. The marking pattern 400 of the embossed shape may indicate a manufacturer, a manufacturing date, a serial number, etc. A height H (see FIG. 2) of the marking pattern 400 from the bottom surface of the marking groove 310 may be equal to or smaller than the depth D of the marking groove 310. The height H of the marking pattern 400 may be within a range of 10 μm to 50 μm.

Since the marking pattern 400 may be formed by the inkjet printing method and may have the embossed shape, an upper surface of the marking pattern 400 does not have a step with the upper surface of the molding member 300, and does not cause damage to the marking area due to a laser processing method, to thereby prevent stress from being concentrated on the marking area and cracks from being caused during a reliability evaluation such as a subsequent thermal cycle (TC) test.

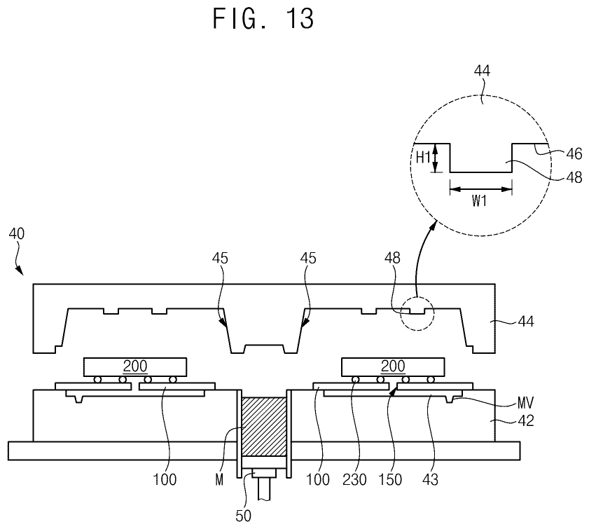

Then, external connection members 500, such as solder balls, may be formed on lower substrate pads 130 on the lower surface of the strip substrate of FIG. 13, and the strip substrate may be individually separated along the cutting region by a sawing process, to complete the semiconductor package 10 (e.g., a flip-chip package) of FIG. 1.

FIG. 12 is a plan view illustrating a semiconductor package in accordance with example embodiments. The semiconductor package may be substantially the same as the semiconductor package described with reference to FIGS. 1 to 3 except for a configuration of a molding material passage hole. Thus, same reference numerals may be used to refer to the same or like elements, and any further repetitive explanation concerning the above elements may be omitted.

Referring to FIG. 12, a package substrate 100 of a semiconductor package 11 may include at least one molding material passage hole 150 within a chip mounting region MR. The molding material passage hole 150 may be formed to penetrate the package substrate 100. The molding material passage hole 150 may be formed to penetrate a portion of an insulating layer (e.g., the first upper insulating layer 120 and/or the lower insulating layer 140) where internal circuit wirings are not formed. For example, a plurality of the molding material passage holes 150 may be arranged to be spaced apart from each other in one direction (e.g., the X direction or the Y direction). The molding material passage holes 150 may be arranged along a center line passing through the center of the chip mounting region MR.

In example embodiments, a semiconductor chip 200 may be placed on the chip mounting region MR. The semiconductor chip 200 may be mounted on the chip mounting region MR of the package substrate 100 via conductive bumps 230. A molding member 300 may cover the semiconductor chip 200 on the package substrate 100. The molding member may include an epoxy mold compound (EMC). The molding member 300 may be formed by a molded underfill (MUF) process using a molding apparatus.

The molding member 300 may include a first molding portion 302 that covers an upper surface of the semiconductor chip 200, and a second molding portion 304 that covers an upper surface of the package substrate 100 around the semiconductor chip 200. The first molding portion 302 of the molding member 300 may have a height within a range of 150 μm to 250 μm from the upper surface of the semiconductor chip 200. In addition, the molding member 300 may include a third molding portion 306 that fills a gap between the package substrate 100 and the semiconductor chip 200, and a fourth molding portion 308 filling the at least one molding material passage hole 150.

Hereinafter, a method of manufacturing the semiconductor package of FIG. 12 will be described.

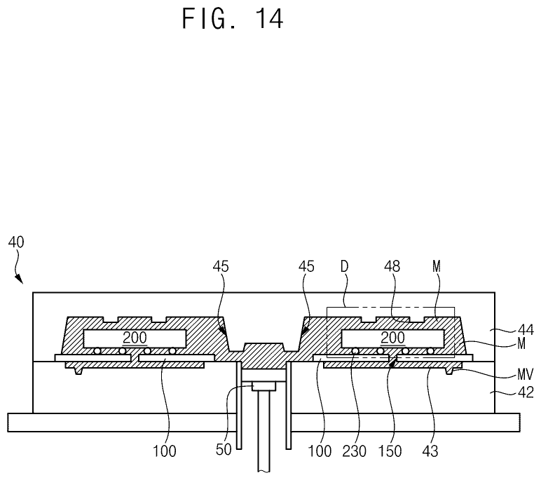

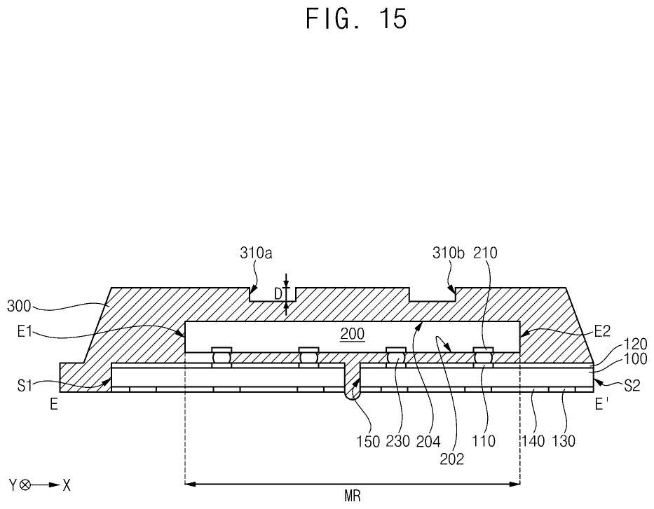

FIGS. 13 and 14 are views illustrating a process of forming a molding member on a package substrate by a molding apparatus. FIG. 15 is a cross-sectional view illustrating the molding member formed on the package substrate by the molding apparatus of FIG. 13.

First, processes the same as or similar to the processes described with reference to FIGS. 4 and 5 may be performed to mount a semiconductor chip 200 on a package substrate 100 with conductive bumps 230 interposed therebetween.

In example embodiments, the semiconductor chip 200 may be mounted on a chip mounting region MR of the package substrate 100 by a flip chip bonding method. The package substrate 100 may have at least one molding material passage hole 150 within the chip mounting region MR.

Referring to FIGS. 13 to 16, a molding member 300 may be formed on the package substrate 100 to cover the semiconductor chip 200.

As illustrated in FIGS. 13 and 14, a molded underfill (MUF) process may be performed using a molding apparatus 40. The molding apparatus 40 may include a mold having a lower mold 42 and an upper mold 44 that are clamped to each other to form a molding space 45 for molding the semiconductor chips 200. The molding apparatus 40 may be a transfer molding apparatus that transfers a liquid molding material (e.g., the molding material M) into the molding space 45 to mold the semiconductor chips 200.

When the molding material M is injected into the molding space 45 (e.g., a cavity) during the molded underfill (MUF) process, the air inside the molding space 45 may be exhausted to the outside through the molding material passage hole 150 to improve resin filling rate. The molding material M may fill the interior of the molding material passage hole 150 and then may be collected into a molding material reservoir MV through a molding material flow channel 43 of the lower mold 42.

As illustrated in FIG. 15, the molding member 300 formed by the molding apparatus 40 may have at least one marking groove 310 on the upper surface of the molding member 300 corresponding to a protruding rib 48 of the molding apparatus 40.

Then, processes the same as or similar to the processes described with reference to FIG. 11 may be performed to form at least one marking pattern (e.g., marking pattern 400 of FIG. 12) in the at least one marking groove 310 of the molding member 300.

Then, external connection members 500 such as solder balls may be formed on lower substrate pads 130 at (e.g., in or on) a lower surface of the package substrate 100 of FIG. 15, and the package substrate 100 may be individually separated along a cutting region by a sawing process, to complete the semiconductor package 11 (e.g., a flip-chip package) of FIG. 12.

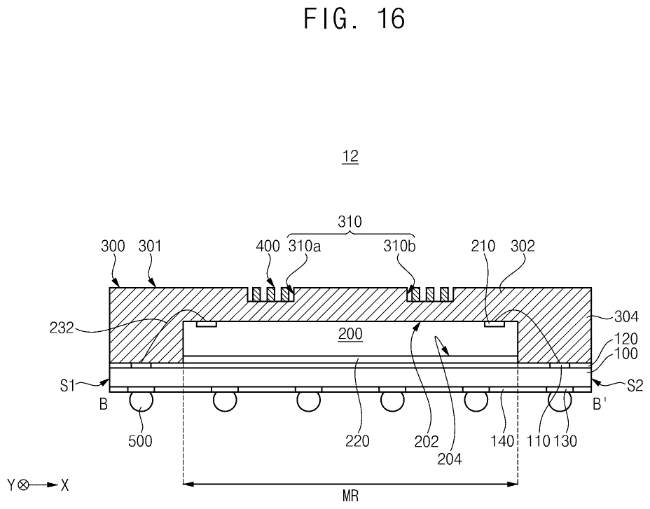

FIG. 16 is a cross-sectional view illustrating a semiconductor package in accordance with example embodiments. The semiconductor package may be substantially the same as the semiconductor package described with reference to FIGS. 1 to 3 except for a mounting manner of a semiconductor chip. Thus, same reference numerals may be used to refer to the same or like elements, and any further repetitive explanation concerning the above elements may be omitted.

Referring to FIG. 16, a semiconductor package 12 may include a package substrate 100, a semiconductor chip 200 disposed on the package substrate 100, a molding member 300 covering the semiconductor chip 200 on the package substrate 100, and a marking pattern 400 provided on an upper surface of the molding member 300. In addition, the semiconductor package 12 may further include external connection members 500.

In example embodiments, the semiconductor chip 200 may be attached to a chip mounting region MR of the package substrate 100 by an adhesive film 220. The semiconductor chip 200 may be attached to the package substrate 100 by using the adhesive film 220 (e.g., a die attach film (DAF) used in a die attach process).

The semiconductor chip 200 may be placed such that a backside surface 204 (e.g., an inactive surface), opposite to a frontside surface 202 at (e.g., in or on) which chip pads 210 are formed, faces the package substrate 100. The semiconductor chip 200 may have a rectangular shape with four sides when viewed in a plan view. A thickness of the adhesive film 220 may be within a range of 20 μm to 60 μm.

The chip pads 210 of the semiconductor chip 200 may be electrically connected to the upper substrate pads 110 of the package substrate 100 by bonding wires 232 as the conductive connection members.

In example embodiments, the molding member 300 may cover (e.g., surround) the semiconductor chip 200 and the bonding wires 232 on the package substrate 100. The molding member 300 may have at least one marking groove 310 provided in the upper surface 301 of the molding member 300. The marking groove 310 may have an engraved shape with a depth D (e.g., a preset depth) from the upper surface 301 of the molding member 300. A marking pattern 400 may be provided in the marking groove 310 formed in the upper surface 301 of the molding member 300. The marking pattern 400 may be formed by applying a liquid on a bottom surface of the marking groove 310 using an inkjet printing method.

According to some example embodiments of the present disclosure, a method of manufacturing a semiconductor package may be provided and include: providing a semiconductor chip on a package substrate with conductive bumps interposed between the semiconductor chip and the package substrate; forming a molding member on the semiconductor chip and the package substrate, the molding member including at least one marking groove in an upper surface of the molding member; and providing at least one marking pattern in the at least one marking groove.

According to some example embodiments of the present disclosure, the forming may include forming the molding member using a molding apparatus by: seating the package substrate on a seating surface of a lower mold of the molding apparatus; forming a molding space by engaging an upper mold of the molding apparatus with the lower mold; and forming the molding member, including the at least one marking groove, with a molding material by supplying the molding material into the molding space such that the molding material flows into a first space between the semiconductor chip and the package substrate and into a second space above the semiconductor chip.

According to some example embodiments of the present disclosure, the molding apparatus may further include at least one protruding rib protruding from a lower surface of the upper mold, and wherein the at least one marking groove corresponds to the at least one protruding rib.

According to some example embodiments of the present disclosure, the providing the at least one marking pattern may include forming the at least one marking pattern by an inkjet printing method.

Semiconductor packages, according to embodiments of the present disclosure, may include semiconductor devices such as logic devices or memory devices. The semiconductor packages may include logic devices such as central processing units (CPUs), main processing units (MPUs), or application processors (APs), or the like, and volatile memory devices such as DRAM devices, high bandwidth memory (HBM) devices, or non-volatile memory devices such as flash memory devices, PRAM devices, MRAM devices, ReRAM devices, or the like.

The foregoing is illustrative of example embodiments and the present disclosure is not limited to the example embodiments. Although a few example embodiments have been described, those skilled in the art will readily appreciate that many modifications are possible in example embodiments without departing from the spirit and scope of the present disclosure. Accordingly, all such modifications are intended to be included within the scope of the present disclosure.

What is claimed is:

1. A semiconductor package, comprising:
a package substrate comprising a chip mounting region;
a semiconductor chip on the chip mounting region of the package substrate;
a molding member on the semiconductor chip and the package substrate, the molding member including at least one marking groove in an upper surface of the molding member; and
at least one marking pattern in the at least one marking groove.

2. The semiconductor package of claim 1, wherein the at least one marking groove has a depth from the upper surface of the molding member, and the at least one marking pattern has a height from a bottom surface of the at least one marking groove, and
each of the depth and the height is within a range of 10 μm to 50 μm.

3. The semiconductor package of claim 2, wherein the height of the at least one marking pattern is equal to or smaller than the depth of the at least one marking groove.

4. The semiconductor package of claim 1, wherein the at least one marking pattern comprises ink.

5. The semiconductor package of claim 1, wherein, in a plan view of the semiconductor package, the molding member comprises a first side portion and a second side portion that extend in a first direction, wherein the first side portion and the second side portion face away from each other, and
wherein the at least one marking groove comprises a rectangular shape having a length in the first direction and a width in a second direction perpendicular to the first direction.

6. The semiconductor package of claim 5, wherein the length in the first direction of the rectangular shape of the at least one marking groove is within a range of 5 mm to 10 mm, and the width in the second direction of the rectangular shape of the at least one marking groove is within a range of 1 mm to 3 mm.

7. The semiconductor package of claim 5, wherein the at least one marking groove comprises a first marking groove and a second marking groove that are spaced apart from each other in the second direction.

8. The semiconductor package of claim 1, wherein chip pads of the semiconductor chip are connected to substrate pads of the package substrate via conductive bumps,
wherein the conductive bumps are on the chip pads of the semiconductor chip, and
wherein the molding member is in a gap between the package substrate and the semiconductor chip.

9. The semiconductor package of claim 1, wherein the package substrate comprises at least one molding material passage hole within the chip mounting region, and a portion of the molding member is in the at least one molding material passage hole.

10. The semiconductor package of claim 1, wherein the molding member comprises an epoxy mold compound (EMC).

11. A semiconductor package, comprising:
a package substrate comprising a chip mounting region;
a semiconductor chip on the chip mounting region of the package substrate, wherein the semiconductor chip comprises a first surface that faces the package substrate, and conductive bumps are on the first surface;
a molding member on the semiconductor chip and the package substrate, wherein the molding member includes at least one marking groove in an upper surface of the molding member; and
at least one marking pattern in the at least one marking groove, the at least one marking pattern comprising a protrusion shape,
wherein the at least one marking pattern comprises an ink material.

12. The semiconductor package of claim 11, wherein the at least one marking groove has a depth from the upper surface of the molding member, and the at least one marking pattern comprises a height from a bottom surface of the at least one marking groove, and
wherein each of the depth and the height is within a range of 10 μm to 50 μm.

13. The semiconductor package of claim 12, wherein the height of the at least one marking pattern is equal to or smaller than the depth of the at least one marking groove.

14. The semiconductor package of claim 11, wherein, in a plan view of the semiconductor package, the molding member comprises a first side portion and a second side portion that extend in a first direction, wherein the first side portion and the second side portion face away from each other, and
wherein the at least one marking groove comprises a rectangular shape having a length in the first direction and a width in a second direction perpendicular to the first direction.

15. The semiconductor package of claim 14, wherein the length in the first direction of the rectangular shape of the at least one marking groove is within a range of 5 mm to 10 mm, and the width in the second direction of the rectangular shape of the at least one marking groove is within a range of 1 mm to 3 mm.

16. The semiconductor package of claim 14, wherein the at least one marking groove comprises a first marking groove and a second marking groove that are spaced apart from each other in the second direction.

17. The semiconductor package of claim 11, wherein the molding member is in a gap between the package substrate and the semiconductor chip.

18. The semiconductor package of claim 11, wherein the package substrate includes at least one molding material passage hole within the chip mounting region, and a portion of the molding member is in the at least one molding material passage hole.

19. The semiconductor package of claim 11, wherein the molding member comprises an epoxy mold compound (EMC).

20. A semiconductor package, comprising:
a package substrate comprising a chip mounting region, and at least one molding material passage hole in the chip mounting region;
a semiconductor chip on the chip mounting region of the package substrate, wherein the semiconductor chip comprises a first surface that faces the package substrate, and conductive bumps are on the first surface;
a molding member on the semiconductor chip and the package substrate, the molding member being in a gap between the package substrate and the at least one molding material passage hole, and the molding member including at least one marking groove in an upper surface of the molding member; and
at least one marking pattern in the at least one marking groove, the at least one marking pattern comprising a protrusion shape,
wherein each of a depth of the at least one marking groove from the upper surface of the molding member and a height of the at least one marking pattern from a bottom surface of the at least one marking groove is within a range of 10 μm to 50 μm.
